(19) United States
(12) Patent Application Publication
(10) Pub. No.: US 2014/0267756 A1
(43) Pub. Date: Sep. 18, 2014

(54) Microbolometer supported by glass substrate

(71) Applicant: QUALCOMM MEMS Technologies, Inc., San Diego, CA (US)

(72) Inventors: Evgeni Gousev, Saratoga, CA (US); David W. Burns, San Jose, CA (US); Nicholas I. Buchan, San Jose, CA (US); Ana R. Londergan, Santa Clara, CA (US)

(73) Assignee: QUALCOMM MEMS Technologies, Inc., San Diego, CA (US)

(21) Appl. No.: 13/815,850

(22) Filed: Mar. 14, 2013

(51) Int. Cl. G01J 5/20; H01L 27/12

(52) U.S. Cl. CPC G01J 5/20; H01L 27/1259
USPC 348/164; 250/338.4; 438/54

(57) ABSTRACT

This disclosure provides systems, methods and apparatus for forming microbolometers on glass substrates. In one aspect, the formation of microbolometers on glass substrates can reduce the size and cost of the resultant array and associated circuitry. In one aspect, a portion of the measurement and control circuitry can be formed by thin-film deposition on the glass substrate, while sensitive measurement and control circuitry can be formed on ancillary CMOS substrates. In one aspect, the microbolometers may be packaged using a variety of techniques, including a wafer-level packaging process or a pixel-level packaging process.

### TECHNICAL FIELD

This disclosure is related to long-wave infrared (LWIR) sensors, particularly microbolometers.

### DESCRIPTION OF THE RELATED TECHNOLOGY

Long-wave infrared (LWIR) cameras detect infrared radiation, and convert the detected infrared radiation into an image that can illustrate the heat emission pattern of a viewed area. Such cameras can be used in a variety of applications, including surveillance, building inspection, safety systems, and other applications in which heat emission patterns may be captured or analyzed.

In particular, transmission of LWIR radiation through the atmosphere has a peak in the 8-12 μm range. By utilizing components which also transmit substantial amounts of LWIR radiation within this range, the efficiency of the LWIR radiation transmission and detection can be increased. Typical camera components, such as ordinary glass, may not be sufficiently transmissive to LWIR radiation to be used in an LWIR camera, requiring the optical elements to be formed from specific LWIR-transmissive materials, such as germanium, chalcogenide glass, or low-oxygen silicon.

### SUMMARY

The systems, methods and devices of this disclosure each have several innovative aspects, no single one of which is solely responsible for the desirable attributes disclosed herein. One innovative aspect of the subject matter described in this disclosure can be implemented in an apparatus including a glass substrate, an active matrix array formed over the glass substrate, the active matrix array including a plurality of thin-film transistors (TFTs), an array of microbolometer sensors supported by the glass substrate and electrically connected to the active matrix array, each of the microbolometer sensors including a long-wave infrared (LWIR) absorber suspended over the glass substrate, and a thermistor disposed adjacent the LWIR absorber, an LWIR-transmissive layer overlying at least one of the microbolometer sensors, and at least one ancillary CMOS substrate electrically connected to the active matrix array.

In some implementations, the at least one ancillary CMOS substrate can include measurement or control circuitry. In some implementations, the at least one ancillary CMOS substrate is bonded to the glass substrate. In further implementations, the active matrix array and array of microbolometer sensors can be located over a first surface of the glass substrate, and the at least one ancillary CMOS substrate can be bonded to a second surface of the glass substrate opposite the first surface of the glass substrate. In still further implementations, the apparatus can additionally include at least one via extending between the first surface of the glass substrate and the second surface of the glass substrate and forming at least a part of an electrical connection between the ancillary CMOS circuitry and the active matrix array.

In some implementations, both the glass substrate and the at least one ancillary CMOS substrate can be bonded to a carrier substrate. In further implementations, at least a portion of the glass substrate, the carrier substrate, and the at least one ancillary CMOS substrate can be encapsulated by a packaging material without occluding the array of microbolometer sensors.

In some implementations, the active matrix array can include a row address decoder and a column output multiplexer. In further implementations, the apparatus can additionally include a second ancillary CMOS substrate, where the first ancillary CMOS substrate is electrically connected to the row address decoder and includes control circuitry, and the second ancillary CMOS substrate is electrically connected to the column output multiplexer and includes measurement circuitry.

In some implementations, each microbolometer sensor can additionally include an LWIR reflector underlying and spaced apart from the LWIR absorber and the thermistor. In further implementations, the LWIR reflector can include a getter material.

In some implementations, the apparatus can additionally include a window substrate sealed to the glass substrate by a seal to form a hermetically sealed cavity surrounding the array of microbolometer sensors, where the window substrate includes the LWIR-transmissive layer. In at least a first further implementation, the pressure within the hermetically sealed cavity can be less than about 0.1 mbar. In at least a second further implementation, the seal can include a plurality of metal layers bonded to one another. In at least a first still further implementation, two adjacent metal layers in the plurality of metal layers can include the same metal. In at least a second still further implementation, the apparatus can additionally include a passivation layer extending between a portion of the seal and a conductive component within or electrically connected to the active matrix array. In at least a third further implementation, the seal can include an adhesion layer or an electroplating seed layer. In at least a fourth further implementation, the seal can be a low temperature seal including silicon oxide. In at least a fifth further implementation, the window substrate can include a recess in a portion of the window substrate overlying the array of microbolometer sensors. In still further implementations, the recess is located between standoff structures formed on the window substrate.

In some implementations, the LWIR-transmissive layer can include germanium. In some implementations, the apparatus can additionally include at least one LWIR anti-reflection layer located on a surface of the LWIR-transmissive layer overlying the array of microbolometer sensors. In some implementations, at least a portion of the microbolometer sensors can serve as reference pixels. In at least a first further implementation, the apparatus can additionally include an LWIR-opaque material overlying the microbolometer sensors that serve as reference pixels. In at least a first further implementation, the microbolometer sensors that serve as reference pixels can be thermally sunk to the glass substrate.

In some implementations, the apparatus can be an LWIR camera, and the glass substrate, the active matrix array, the array of microbolometer sensors, the LWIR-transmissive layer, and the at least one ancillary CMOS substrate can form at least a portion of a focal plane array within the LWIR camera.

Another innovative aspect of the subject matter described in this disclosure can be implemented in a method of fabricating a microbolometer device, including forming an active matrix array over a glass substrate, where the active matrix array includes a plurality of thin-film transistors (TFTs), forming an array of microbolometer sensors over at least a portion of the active matrix array, where each of the microbolometer sensors include: a long-wave infrared (LWIR) absorber suspended over the glass substrate, and a thermistor disposed adjacent the LWIR absorber, forming at least one hermetically-sealed package encapsulating the array of microbolometer sensors and including an LWIR-transmissive layer overlying at least one of the microbolometer sensors, and electrically connecting, the active matrix array to at least one ancillary CMOS substrate including measurement or control circuitry.

In some implementations, forming an active matrix array can additionally include forming a row address decoder and a column output multiplexer, and electrically connecting the active matrix array to at least one ancillary CMOS substrate including measurement or control circuitry can include electrically connecting a first ancillary CMOS substrate including control circuitry to the row address decoder, and electrically connecting a second ancillary CMOS substrate including measurement circuitry to the column output multiplexer.

In some implementations, forming at least one hermetically-sealed package encapsulating the array of microbolometer sensors can include sealing a window substrate including the LWIR-transmissive layer to the glass substrate. In further implementations, sealing the window substrate to the glass substrate can include one of bonding at least two metal layers together using one of a thermocompression process, a plasma bonding process, or a metal diffusion bonding process, or using laser annealed compression bonding, anodic bonding, fusion bonding, a layer of frit glass, or a low-temperature seal including silicon oxide.

In some implementations, forming an array of microbolometer sensors over at least a portion of the active matrix array can include forming a layer of sacrificial material over at least a portion of the active matrix array, forming the LWIR absorbers and thermistors over the layer of sacrificial material, and performing a release etch to remove the layer of sacrificial material. In further implementations, the sacrificial material can include a fluorine-etchable sacrificial material.

Another innovative aspect of the subject matter described in this disclosure can be implemented in an apparatus, including a glass substrate, an active matrix array formed over the glass substrate, the active matrix array including a plurality of thin-film transistors (TFTs), an array of microbolometer sensors supported by the glass substrate and electrically connected to the active matrix array, each of the microbolometer sensors including: a long-wave infrared (LWIR) absorber suspended over the glass substrate, and a thermistor disposed adjacent the LWIR absorber, means for hermetically encapsulating the array of microbolometer sensors, an LWIR-transmissive layer overlying at least one of the microbolometer sensors, and at least one ancillary CMOS substrate electrically connected to the active matrix array.

In some implementations, the encapsulating means can include a window substrate sealed to the glass substrate. In further implementations, a portion of the window substrate overlying the array of microbolometer sensors can serve as the LWIR-transmissive layer. In further implementations, the window substrate can support the LWIR-transmissive layer.

Another innovative aspect of the subject matter described in this disclosure can be implemented in an apparatus, including a glass substrate, an active matrix array formed over the glass substrate, the active matrix array including a plurality of thin-film transistors (TFTs), an array of microbolometer sensors supported by the glass substrate and electrically connected to the active matrix array, each of the microbolometer sensors including a long-wave infrared (LWIR) absorber suspended over the glass substrate, and a thermistor disposed adjacent the LWIR absorber, a plurality of shell structures, each shell structure encapsulating a portion of the array of microbolometer sensors, where at least a portion of the plurality of shell structures include an LWIR-transmissive layer overlying at least one microbolometer sensor.

In some implementations, the apparatus can additionally include at least one ancillary CMOS substrate electrically connected to the active matrix array, where the at least one ancillary CMOS substrate includes measurement or control circuitry. In at least a first further implementation, the at least one ancillary CMOS substrate can be bonded to the glass substrate. In still further implementations, the active matrix array and array of microbolometer sensors can be located over a first surface of the glass substrate, and the at least one ancillary CMOS substrate can be bonded to a second surface of the glass substrate opposite the first surface of the glass substrate. In still further implementations, the apparatus can additionally include at least one via extending between the first surface of the glass substrate and the second surface of the glass substrate and forming at least a part of an electrical connection between the ancillary CMOS circuitry and the active matrix array. In at least a second further implementation, each of the glass substrate and the at least one ancillary CMOS substrate can be bonded to a carrier substrate. In still further implementations, at least a portion of the glass substrate, the carrier substrate, and the at least one ancillary CMOS substrate can be encapsulated by a packaging material without occluding the array of microbolometer sensors. In at least a third further implementation, the active matrix array can include a row address decoder and a column output multiplexer. In still further implementations, the apparatus can additionally include a second ancillary CMOS substrate, where the first ancillary CMOS substrate is electrically connected to the row address decoder and includes control circuitry, and the second ancillary CMOS substrate is electrically connected to the column output multiplexer and includes measurement circuitry.

In some implementations, each of the plurality of shell structures can encapsulate a single microbolometer sensor. In some implementations, each of the plurality of shell structures can include a shell layer having an aperture extending therethrough, and a sealing layer overlying at least the aperture and sealing the aperture. In at least a first further implementation, the aperture can overlie at least a portion of a microbolometer sensor, and the sealing layer can include an LWIR-transmissive material. In at least a first further implementation, the aperture can be laterally offset from any microbolometer sensor within the shell structure, and the sealing layer can include an LWIR-opaque material.

In some implementations, each microbolometer sensor can additionally include an LWIR reflector underlying and spaced apart from the LWIR absorber and the thermistor. In further implementations, the LWIR reflector can include a getter material. In some implementations, at least a portion of the microbolometer sensors can serve as reference pixels. In at least a first further implementation, the apparatus can additionally include an LWIR-opaque material overlying the microbolometer sensors that serve as reference pixels. In at least a second further implementation, the microbolometer sensors that serve as reference pixels can be thermally sunk to the glass substrate.

In some implementations, each shell structure can form a hermetically sealed cavity supported by the glass substrate and encapsulating a portion of the array of microbolometer sensors. In further implementations, the pressure within the hermetically sealed cavity can be less than about 0.1 mbar. In some implementations, the apparatus can be an LWIR camera, and where the glass substrate, the active matrix array, the array of microbolometer sensors, and plurality of shell structures can form a part of a focal plane array within the LWIR camera.

Another innovative aspect of the subject matter described in this disclosure can be implemented in a method of fabricating a microbolometer device, including forming an active matrix array over a glass substrate, where the active matrix array includes a plurality of thin-film transistors (TFTs), forming an array of microbolometer sensors over at least a portion of the active matrix array, where each of the microbolometer sensors include a long-wave infrared (LWIR) absorber suspended over the glass substrate, and a thermistor disposed adjacent the LWIR absorber, forming at least one hermetically-sealed package encapsulating the array of microbolometer sensors and including an LWIR-transmissive layer overlying at least one of the microbolometer sensors, and electrically connecting the active matrix array to at least one ancillary CMOS substrate including measurement or control circuitry.

In some implementations, forming an active matrix array additionally can include forming a row address decoder and a column output multiplexer, and electrically connecting the active matrix array to at least one ancillary CMOS substrate including measurement or control circuitry can include electrically connecting a first ancillary CMOS substrate including control circuitry to the row address decoder, and electrically connecting a second ancillary CMOS substrate including measurement circuitry to the column output multiplexer.

In some implementations, forming a plurality of shell structures can include forming discrete sections of sacrificial material over each of the microbolometer sensors, forming a shell structure over each of the discrete sections of sacrificial material, each shell structure including an aperture extending therethrough, performing a release etch to remove the discrete sections of sacrificial material, and forming a sealing layer over at least the aperture to close the aperture.

In some implementations, the sealing layer can extend over at least a portion of a microbolometer sensor and can include an LWIR-transmissive material. In some implementations, the sealing layer can be laterally offset from any microbolometer sensor within the shell structure and can include an LWIR-opaque material.

Another innovative aspect of the subject matter described in this disclosure can be implemented in an apparatus, including a glass substrate, an active matrix array formed over the glass substrate, the active matrix array including a plurality of thin-film transistors (TFTs), an array of microbolometer sensors supported by the glass substrate and electrically connected to the active matrix array, each of the microbolometer sensors including a long-wave infrared (LWIR) absorber suspended over the glass substrate, and a thermistor disposed adjacent the LWIR absorber, means for hermetically encapsulating discrete portions of the array of microbolometer sensors, and an LWIR-transmissive layer overlying at least one of the microbolometer sensors.

In some implementations, the apparatus can additionally include at least one ancillary CMOS substrate electrically connected to the active matrix array. In some implementations, the encapsulating means can include a plurality of shell structures, each shell structure separately encapsulating only a portion of the array of microbolometer sensors. In at least a first further implementation, each of the plurality of shell structures can encapsulate only a single microbolometer sensor. In at least a second further implementation, a portion of a shell structure can serve as the LWIR-transmissive layer. In some implementations, a shell structure can support the LWIR-transmissive layer.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an example of a long-wave infrared (LWIR) camera core including a focal plane array (FPA) of sensors such as microbolometers.

FIG. 2A shows an example of a cross-sectional schematic illustration of a microbolometer which can be used in the FPA array of the LWIR camera of FIG. 1.

FIG. 2B schematically illustrates an example of sensor circuitry of a microbolometer such as the microbolometer of FIG. 2A.

FIG. 3A is a top plan view schematically illustrating one implementation of a FPA including an array of microbolometers.

FIG. 3B is a top plan view schematically illustrating another implementation of a FPA including an array of microbolometers.

FIGS. 4A-4D show examples of cross-sectional schematic illustrations of various stages in a method of fabricating a microbolometer.

FIGS. 5A-5E show examples of cross-sectional schematic illustrations of various stages in a method of fabricating a microbolometer using a pixel-level packaging process.

FIG. 6 shows an example of a cross-sectional schematic illustration of a microbolometer fabricated using a process such as the processes of FIGS. 4A-4D and FIGS. 5A-5E.

FIG. 7 shows an example of a cross-sectional schematic illustration of a device including an array of pixel-level packaged microbolometers and supplemental control and sensing circuitry.

FIG. 8 shows an example of a flow diagram illustrating a manufacturing process for a microbolometer array including a pixel-level packaging process.

FIGS. 9A-9G show examples of cross-sectional schematic illustrations of various stages in a method of fabricating a microbolometer array using a wafer-level packaging process.

FIG. 10 shows an example of a cross-sectional schematic illustration of a device including an array of pixel-level packaged microbolometers and supplemental control and sensing circuitry.

FIG. 11 shows an example of a flow diagram illustrating a manufacturing process for a microbolometer array including a wafer-level packaging process.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways.

FIG. 1 shows an example of an LWIR camera core including a focal plane array (FPA) of sensors such as microbolometers. The LWIR camera core 10 includes a housing 20 and an LWIR lens 30 or other optical element which allows focusing of the LWIR light passing into the housing 20. Located in the path of LWIR light passing through the LWIR lens 30 is a focal plane array (FPA) 40, which includes an array of LWIR-sensitive components such as microbolometers. Additional electronics 50 may be located either within or outside of the housing 20, or in both locations, but are schematically represented in FIG. 1 as a single block within the housing 20.

The FPA 40 is typically a hermetic package including a supporting substrate, a read-out integrated circuit (ROIC), an overlaid sensor array such as an array of microbolometers or other LWIR-sensitive elements, and an LWIR-transmissive window joined to the substrate to form a part of the hermetic package. In some implementations, the ROIC can consist of a switch array, control circuitry, and one or more measurement circuits. In an implementation in which the FPA is formed on a silicon substrate, all components of the ROIC can be integrally formed on the silicon substrate using CMOS technology.

A typical LWIR camera core such as core 10 of FIG. 1 can cost thousands of dollars, and can have a size of roughly 15 cm³. The size and expense make such a camera core impractical for inclusion in a device other than a dedicated LWIR device, such as an expensive LWIR camera. In contrast, a visible light camera module containing the same amount or a larger number of pixels can have a cost of only a few dollars, and a volume on the order of 0.1 cm³. The visible light camera module, having a cost and size that are orders of magnitude smaller than the LWIR core, can be readily integrated into a wide range of devices, including but not limited to cellular phones and other portable devices.

As noted above, microbolometer arrays are typically formed on silicon substrates. However, by utilizing glass substrates in an LWIR camera module rather than silicon substrates, reductions in both size and cost can be achieved. The thermal conductivity of glass (roughly 1 W/mK) is more than two orders of magnitude less than the thermal conductivity of silicon (roughly 149 W/mK). The increased thermal isolation between adjacent microbolometers formed on a glass substrate allows the overall sensitivity of the microbolometer array to be increased. In some implementations, this enables a reduction of pixel pitch within the array from 17-25 um on silicon substrates to 12 um on glass substrates.

FIG. 2A schematically illustrates certain components of a pixel array for use in an LWIR camera. In particular, FIG. 2A illustrates a cross-section of a single microbolometer pixel 100 within the pixel array. The pixel 100 includes a substrate 110, which includes glass rather than silicon. One or more thin-film transistors (TFTs) 120 may be formed on the substrate 110. In contrast to pixel arrays formed on silicon substrates, the TFT 120 of pixel 110 is formed on a surface of, rather than within, the glass substrate 110. Although schematically represented as a single layer, the TFT 120 can be a stack of layers deposited and patterned to form the TFT 120. In addition, the TFT 120 may form part of an active matrix array that is formed using thin-film deposition processes, which may include multiple TFTs as well as associated routing lines and other circuitry.

In some implementations, depending on the desired sensitivity and complexity of the circuitry, a TFT active matrix including TFT 120 may include only a portion of the measurement and control circuitry used to control the FPA or other device including the microbolometer pixel 100, while the most sensitive measurement and control circuitry can be formed on a separate CMOS substrate and placed in electrical communication with the TFT active matrix including TFT 120. By forming the pixel 100 and underlying active matrix array on a low cost glass substrate, while forming only measurement and control circuitry on an expensive CMOS substrate, the overall cost of the microbolometer can be reduced. In addition, by forming the pixel 100 and underlying active matrix array on the glass substrate, the thermal isolation of the pixels from the surrounding environment, and hence the sensitivity of the bolometer, may be improved.

The pixel 100 may include a long-wave infrared mirror 130 located on the opposite side of a cavity 132 from an overlying suspended sensor 140. The LWIR mirror 130 may be used to reflect at least a portion of infrared light incident on the mirror 130. In some implementations, the LWIR mirror 130 can be a layer of aluminum (Al) with thicknesses ranging from 50-1000 nm, although other materials and other thicknesses both above and below that range may be used. In some implementations, the LWIR mirror 130 may be the top layer within the TFT 120.

The sensor 140 may be supported over the LWIR mirror 130 by arms 134 in electrical communication with electrodes 122. While the arms 134 may include some conductive material in order to electrically connect the sensor 140 to the electrodes 122, the arms 134 may also have a thin cross section so as to achieve a low thermal conduction in order to thermally isolate the sensor 140 from the remainder of the device. Although schematically depicted as distinct structures overlying the TFT 120, the electrodes 122 may be formed within the TFT active matrix array containing TFT 120. A pixel array may include a plurality of pixels such as pixels 100 disposed across the array, with each pixel 100 connected to one or more TFTs 120 and one or more electrodes 122.

The sensor 140 is a multilayer structure including at least a long-wave infrared absorber 142 that absorbs LWIR radiation passing through the sensor 140, and a thermistor 144 adjacent the LWIR absorber 142. While illustrated as underlying the LWIR absorber 142, the thermistor 144 may in other implementations overlie the LWIR absorber 142. The thermistor 144 can be formed from one or more of a variety of materials, including amorphous silicon (a-Si), vanadium oxide (VOₓ), or silicon germanium (SiGe), in thicknesses ranging from 10 nm to 1000 nm, although other materials and other thicknesses of materials may also be used. For example, alternate implementations may utilize silicon (Si), germanium (Ge), polysilicon-germanium (poly SiGe), silicon carbide (SiC), SiCON, vanadium oxide (VOx) with or without the inclusion of tungsten (W), barium strontium titanate (BST), or yttrium barium copper oxide (YBaCuO) as the thermistor 144 material. The LWIR absorber 142 may also be formed from one or more of a variety of materials, including but not limited to titanium nitride (TiN), aluminum (Al), or platinum (Pt) in thicknesses ranging from 5 nm to 100 nm, although other materials and other thicknesses of materials may also be used.

In some implementations, the sensor 140 may contain additional components. For example, in the illustrated implementation, the sensor 140 includes a layer of support material 146. In the illustrated implementation, the layer of support material 146 underlies the thermistor 144 and the LWIR absorber 142, although the layer of support material 146 may in other implementations overlie these or other layers, or lay between the materials. In addition to providing additional physical support to the other components of the sensor 140, the layer of support material 146 may also be used to balance residual stresses within the sensor 140 to prevent undesired flexure of the elements after removal of a supporting sacrificial layer as discussed below.

In some implementations, the sensor 140 may include an LWIR anti-reflection layer, although in other implementations, an LWIR anti-reflection layer may be formed separate from the sensor 140 itself but in the path of incident radiation, such as on a surface of an overlying window 150, as will be discussed in greater detail herein. Suitable materials and thicknesses for an LWIR anti-reflection layer include, but are not limited to, titanium oxide (TiO2), tantalum oxide (Ta2O5), and silicon oxide SiO2, in thicknesses ranging from 5 nm to 1000 nm. The LWIR anti-reflection layer may also be a multilayer stack of layers ranging from 50 nm to 1000 nm.

Although the sensor is depicted in the illustrated implementation as including several individual layers, certain of these functions can be performed by a single layer, which may replace two or more of the depicted layers. For example, a single layer of a titanium-aluminum (TiAl) alloy may serve as both a thermistor and an LWIR absorber, and can even serve as a support membrane.

Overlying the sensor 140 is an LWIR window 150 that allows light in the 8-12 μm wavelength range to pass through, such that the light 162 that passes through the LWIR window 150 includes light with wavelengths in the 8-12 μm range. In some implementations, the LWIR window 150 may also filter incident light 160 to prevent some or all of other wavelengths of light from passing through the LWIR window 150, but in other implementations, filtering of other wavelengths may be performed by structures at an earlier point along the optical path of the light 160 incident upon LWIR window 150, such as at lens 30 of an LWIR camera core 10 (see FIG. 1)

Portions of incident light 162 may pass through the sensor 140, and can then be reflected by the underlying LWIR mirror 130 back into the sensor 140 to increase the sensitivity of the sensor 140 to incident infrared radiation. In some implementations, as discussed elsewhere herein, one or both surfaces of the LWIR window 150 may be coated with an anti-reflective coating (not shown in FIG. 2A).

In some implementations, a thermal ground plane (not shown) can be provided close to the sensors 140 to improve uniformity of the sensors 140, and may include a layer of aluminum nitride (AlN), graphene, copper (Cu), diamond-like carbon, or silicon carbide (SiC). If the thermal ground plane is formed from a conductive material, the thermal ground plane may be electrically isolated from the sensors 140 and/or the active matrix array.

The sensor 140 may be suspended within a moderate vacuum having a pressure of less than about 0.1 mBar. In some implementations, the pressure of the vacuum may be as low as or lower than 0.001 mBar. This level of vacuum may be achieved by hermetically sealing the LWIR window 150 to the substrate 110 as discussed in greater detail below. In some implementations, in order to maintain the vacuum after sealing, it may be advantageous to include a getter inside the pixel that removes various gases: those that leak through the seal, and those that diffuse out of the deposited sensor and TFT layers. In one specific implementation, the underlying LWIR mirror 130 may include a thin film getter that not only functions as an IR mirror, but also is capable of gettering gases.

FIG. 2B schematically illustrates an example of sensor circuitry of an active matrix array underlying and connected to an array of microbolometers such as the microbolometer of FIG. 2A. In particular, the active matrix array 170 includes bolometer drive lines 172 and switch control lines 174 illustrated as running generally in a first direction, such as horizontal. The active matrix array 170 also includes output lines 176 running generally in a second direction which may be substantially perpendicular to the first direction in which the drive lines 172 and switch control lines 174 run. In other implementations, however, other configurations of the drive lines 172, control lines 174, and output lines 176 may be provided, such as an implementation in which the drive lines 172 may run substantially parallel to the output lines 176 and perpendicular to the switch control lines 174.

Each pixel 100 includes a sensor 140 such as a microbolometer, and a switch 105 in electrical communication with a switch control line 174 to allow addressing of that pixel 100. LWIR radiation 162 incident upon an active pixel 100 in which the switch 105 is closed will result in a pixel output on the connected output line 176. Additional TFT structures (not shown) including a row address decoder and a column output multiplexer can be formed elsewhere in the TFT layer. For example, such additional TFT structures can be formed at a periphery of the active matrix array.

In some implementations, reference pixels 106 may be provided that are shielded from or otherwise less affected by incident LWIR radiation to provide for temperature correction or calibration, as the thermistors 144 (see FIG. 2A) in the sensors 140 of the reference pixels 106 can provide an indication of the temperature at the location of the reference pixel 106 regardless of the amount of LWIR light incident upon the array 162, as the reference pixels 106 will be substantially unaffected by incident LWIR light. Depending on the placement of the reference pixels 106 relative to the remainder of the array, the reference pixels 106 may be used to compensate for variation in the overall temperature of the array, or may be used to compensate for localized variations in temperature within the array.

Various implementations of reference pixels may be employed. For example, a pixel may be blocked by a shielding structure 108 that prevents LWIR radiation from reaching a sensor 140 in a reference pixel 106 by absorbing and/or reflecting the LWIR radiation. The shielding structure 108 may be located on a surface of an LWIR window 150 (see FIG. 2A) or similar structure overlying reference pixel 106, or may include a layer of highly LWIR-reflective material within the sensor 140 and overlying or in place of the LWIR-absorbing layer. The size and placement of the shielding structure 108 will depend on the distance between the shielding structure 108 and the sensor 140 in the reference pixel, and other factors that affect the angle of incidence of the light, such as the telecentricity of a lens in an LWIR camera. In other implementations, reference pixels may be thermally sunk to the underlying substrate rather than being suspended and thermally isolated from the underlying substrate. In other implementations, reference pixels may utilize both shielding and thermal sinking.

In some implementations, reference pixels 106 may be disposed on the periphery of a pixel array. In other implementations, reference pixels 106 may be disposed throughout the array, such as in a regular pattern, in order to further improve calibration and correction by providing temperature information throughout the array. Differences in the output signals from reference pixels at different locations within the array may be indicative of temperature gradients or hot/cold spots within the array, and localized correction of the output signals of adjacent LWIR pixels can be performed to provide a more accurate image. When the reference pixels 106 are located throughout the array instead of at the periphery, the reference pixels may form areas within the array unresponsive to LWIR radiation, essentially forming “dead” pixels. However, the reference pixels on an image produced by the array may be compensated for by estimating the LWIR incident upon those reference pixels 106 using interpolation from the data measured by adjacent active pixels.

Although the reference pixel 106 in FIG. 2B is depicted as a normal pixel including a switch 105 and connected to a shared output line 176, other connections are possible. For example, one or more reference pixels may be connected to dedicated output lines to provide a constant indication of the temperature. If multiple reference pixels are connected together, the spatial resolution of the reference pixels may be decreased, but thermal interference due to power dissipation in an always-on pixel may be reduced.

FIG. 3A is a top plan view schematically illustrating one implementation of a FPA including an array of microbolometers. In the implementation of FIG. 3A, the FPA 400A is a chip scale package (CSP) in which a glass substrate 410 including an array 420 of microbolometers and an underlying active matrix TFT array is bonded to a carrier substrate 412 such as a lead frame. In the illustrated implementation, the active matrix TFT array extends beyond the overlying array 420 of microbolometers on two adjacent sides, and includes a row address decoder 432 formed on a first side and a column output multiplexer 442 formed along a second adjacent side of the array 420 of microbolometers. Bond regions 434 and 444 in communication with the row address decoder 432 and the column output multiplexer 442, respectively, may be used to form wire bonds or other suitable electrical connections between components on the glass substrate 410 and ancillary CMOS circuitry 436 and 446 separately bonded to the carrier substrate 412. Depending on the types of transistors used in the row address decoder 432, the number of signal lines bonded to the control can be reduced, with a greater reduction of signal lines possible when the row address decoder 432 includes complementary transistors rather than single dopant-type transistors. Similarly, the column output multiplexer 442 can reduce the number of column outputs, with greater reductions possible when the number of control signals increases.

In one implementation, the ancillary CMOS control circuitry 436 may include digital control and/or driver circuitry, which is configured to receive power and digital control signals from an external input source (not shown). The control CMOS circuitry 436 may power the pixel array, and may address both the drive lines as well as the switch lines within the active matrix TFT array.

The measurement CMOS circuitry 446 may receive outputs from the column output multiplexer 442, and output measurement data to external circuitry or an external processor (output pads and external circuitry or processor are not shown). The measurement CMOS circuitry 446 may include analog signal conditioning circuitry, an analog-to-digital converter (ADC) and data drivers, each of which may operate on the received output signals to generate measurement data to be output. The measurement CMOS circuitry 446 may also receive control and synchronization signals from the control CMOS circuitry 436, whether directly or through the TFT array, and the control CMOS circuitry 436 may also send column select data to the column output multiplexer 442.

FIG. 3B is a top plan view schematically illustrating another implementation of an FPA including an array of microbolometers. The FPA 400B of FIG. 3B differs from the FPA 400A of FIG. 3A in that the FPA 400B is a chip-on-glass module which does not utilize a separate carrier substrate or lead frame, but instead mounts ancillary CMOS circuitry 436 and 446 on or over a surface of the glass substrate 410 using chip-on-glass mounting. Depending on the side of the substrate 410 to which the ancillary CMOS circuitry 436 and 446 is mounted, the ancillary CMOS circuitry 436 and 446 may be placed in electrical communication with the microbolometer array 420 and underlying active matrix TFT array through some combination of wiring, electrical leads or traces, bonding with anisotropic conductive film (ACF), and through-glass vias. The ancillary CMOS circuitry 436 and 446 may be in electrical communication with input pads 438 and output pads 448 respectively, or other suitable structure for providing input and/or output to the FPA 400B. The use of the opposite surface of the substrate to support the ancillary CMOS circuitry 436 and 446 can allow a reduction in the overall size of the FPA 400B relative to that of FPA 400A (FIG. 3A). In addition, the input and output pads can in such an implementation also be located on the opposite surface of the substrate 410 from the microbolometer array 420.

FIGS. 4A-4D show examples of cross-sectional schematic illustrations of various stages in a method of fabricating a microbolometer. The method begins by forming an active matrix array including one or more TFTs 220 on a glass substrate 210, as shown in FIG. 4A. As discussed above, while schematically illustrated as a single layer, the TFT 220 may be formed by sequentially depositing and/or patterning multiple thin-film layers to form an array of TFTs such as TFT 220 and associated circuitry.

In FIG. 4B, the method continues by forming an LWIR reflector 230 and electrodes 222. As discussed above, although depicted as elements distinct from the multilayer structure of TFT 220, all or part of LWIR reflector 230 and electrodes 222 may be incorporated within the structure of TFT 220 or the remainder of the thin-film active matrix array which includes TFT 220. For example, as discussed above, the top layer of the TFT 220 may serve as at least a portion of the LWIR reflector 230, and a conductive layer within the TFT 220 or another portion of the thin-film active matrix, of which the TFT 220 is a part, can serve as all or part of the electrodes 222.

In FIG. 4C, a first layer 236 of a sacrificial material has been deposited over the TFT 220, the LWIR reflector 230, and the electrodes 222. In some implementations, the first sacrificial layer 236 may include a polymeric or a non-polymeric material. In an implementation in which the sacrificial layer 236 includes a polymeric material, the sacrificial layer may be an oxygen-etchable polymer. In an implementation in which the sacrificial layer 236 includes a non-polymeric material, the sacrificial layer may be a fluorine-etchable material, such as molybdenum (Mo), tungsten (W), or amorphous silicon (a-Si). The sacrificial layer will at least in part define the height of the resultant cavity between the suspended sensor and the underlying LWIR reflector 230 and other underlying components or layers. In some implementations, the first sacrificial layer can be between 1 and 3 um. As discussed above with respect to other layers, other suitable materials and thicknesses of materials may also be used for the first sacrificial layer 236.

The sacrificial layer 236 may include apertures 238 extending from the top surface of sacrificial layer 236 to an exposed surface of electrode 222 or other conductive surface. In some implementations, the apertures 238 are formed after deposition of the first sacrificial layer 236 by a patterning and etching process. The dimensions and shape of these apertures 238 will determine the dimensions and shape of the support arms which will suspend the sensor. In one implementation, the apertures 238 may include a ramp or angled surface that extends upward from the electrode 222. Such angled apertures may allow the formation of support arms which are longer than the height of the sacrificial layer, as they will extend upward and at an angle to the underlying layers, further increasing the thermal isolation of the supported sensor.

In FIG. 4D, support arms 234 are formed within apertures 238 (FIG. 4C). As discussed above, these support arms may be vertical, or may be formed at an angle to further increase the isolation of the suspended sensor 240. At least a portion of the support arms may be conductive to provide an electrical connection between the sensor 240 and the underlying electrodes 222. In some implementations, two support arms per sensor may be formed, while in other implementations, more than two support arms are formed, and in other implementations, less than two support arms are formed. In some implementations, four support arms are formed, each one on a side of a generally rectangular or square sensor.

Sensor 240 is also formed over the first sacrificial layer 236 by depositing one or more layers over the sacrificial layer and patterning the deposited one or more layers to form sensor 240. In the illustrated implementation, a support layer 246 is deposited over the first sacrificial layer 236, followed by a thermistor 244 and an LWIR absorber 242. In some implementations, the three layers which form the support layer 246, the thermistor 244 and the LWIR absorber 242 are deposited prior to patterning of any of those layers, while in other implementations, at least some of these layers may be patterned before an overlying layer is deposited. In some implementations, a single etch may be used to pattern all three layers, while in other implementations, multiple etches may be used. In some implementations the sensor 240 may be perforated with holes that enable the first sacrificial layer to be readily removed, particularly when the first sacrificial layer has a very high aspect ratio and is much larger in one or more dimensions than in other dimensions.

In some implementations, at least some of the layers which form sensor 240 can also be used to form the support arms 234. In other implementations, support arms 234 can be formed and patterned prior to deposition of the layers that form sensor 240. Although the support arms and the sensor 240 appear to encapsulate a portion of the sacrificial layer 236, the support arms 234 may be relatively narrow in the plane out of the picture. Because of the dimensions of the support arms 234, a substantial amount of the first sacrificial layer 236 underlying the sensor 240 remains connected to adjacent portions after the formation of the support arms 234 and overlying sensor layers 240. The contiguous first sacrificial layer 236 facilitates removal of the first sacrificial layer 236 in a subsequent step, including the portions between support arms 234.

The resultant structure after the steps of FIG. 4D is a microbolometer which still includes a first sacrificial layer 236 between the sensor 240 and an underlying LWIR reflector 230. Such a structure may be referred to as an unreleased microbolometer, or an unreleased microbolometer array. Subsequent to the formation of such an unreleased microbolometer array, additional processing steps can be used to package the microbolometer array and form a structure such as an FPA. Two specific implementations are discussed in turn below.

FIGS. 5A-5E show examples of cross-sectional schematic illustrations of various stages in a method of fabricating a microbolometer using a pixel-level packaging process. Subsequent to the steps of FIGS. 4A-4D or a similar process of forming an unreleased microbolometer or microbolometer array, a second sacrificial layer 256 is deposited over the sensor 240 and the first sacrificial layer 236 as shown in FIG. 5A, and patterned to remove portions of the sacrificial layers 256 and 236 located away from the sensor 240, leaving a shell of sacrificial material extending both vertically upward over the sensor 240 as well as laterally outward, so as to surround the sensor 240 on the substrate 210. Similar sections of sacrificial material formed from patterned portions of sacrificial layers 256 and 236 surround other sensors 240 (not shown) on the substrate 210.

In some implementations, the second sacrificial layer 256 may be an oxygen-etchable polymer, or may be a fluorine-etchable material, such as Mo, W, or a-Si. In some implementations, the second sacrificial layer 256 includes the same material as the first sacrificial layer 236, or a material which is etchable by the same etch chemistry as the material of the first sacrificial layer, so that both sacrificial layers 236 and 256 can be etched by a single release etch in a subsequent step. In some implementations, the second sacrificial layer 256 can be between 5 and 20 um, and may be thicker than the first sacrificial layer 236. Because the second sacrificial layer 256 will define a distance between the sensor 240 and an overlying protective shell, the additional spacing between the sensor 240 and the shell due to the thicker second sacrificial layer 256 will protect against mechanical interference with or damage to the sensor 240.

In FIG. 5B, a protective shell layer 254 has been deposited over the second sacrificial layer 256 and the exposed portions of the first sacrificial layer 236, encapsulating the sacrificial layer and the sensor 240. Because the shell layer 254 will overlie at least a portion of the sensor 240, the shell layer 254 must be formed from LWIR-transmissive material or materials in order to allow operation of the sensor 240 packaged therein. In some implementations, for example, the shell layer 254 may include a layer of germanium (Ge), but a wide variety of other LWIR-transmissive materials may be suitable as well. In other implementations, the shell layer 254 may include zinc sulfide (ZnS), zinc selenide (ZnSe), arsenic trisulfide (As₂S₃), gallium arsenide (GaAs) germanium arsenic selenide (GeAsSe), calcium fluoride (CaF₂), magnesium fluoride (MgF₂), barium fluoride (BaF₂), or potassium chloride (KCl). Depending on the material used and other considerations discussed in greater detail below, the thickness of the shell layer 254 may in some implementations have a thickness between 100 nm and 200 um, although other thicknesses and materials may also be used in other implementations. In some implementations, the shell layer 254 can be formed from multiple materials, so long as the portion overlying the sensor 240 is sufficiently transmissive to LWIR light. For example, the sides of the shell layer 254 may be formed from a different material in a multi-step fabrication process.

In some implementations, the shell layer 254 may have a substantially constant thickness, and be conformally deposited over the underlying sacrificial layers 236 and 256, while in other implementations, portions of the shell layer 254 may be thicker than other portions. Although the shell of sacrificial layers 236 and 256 is illustrated as having substantially vertical sides, these sacrificial layers 236 and 256 may in other implementations have a generally frustroconical shape or otherwise have tapered sidewalls, in order to facilitate deposition of the shell layer 254 over the sacrificial layers 236 and 256.

In FIG. 5C, an aperture 255 is formed in the protective shell layer to expose a portion of the underlying sacrificial layer 256 (FIG. 5B). The apertures 255 may be formed, for example, by a patterning and etching step with a suitable etchant.

In FIG. 5D, a release etch is performed to remove sacrificial layers 236 and 256. The removal of these sacrificial layers 236 and 256 forms a cavity 232 between the sensor 240 and the LWIR mirror 230 and a larger cavity 252 between the shell 254 and the sensor 240. A process may also be performed after the release etch to remove contaminants from within the shell 254 to ensure good device performance and/or from the surface of the shell 254 to ensure good adhesion to subsequently deposited layers or materials.

In FIG. 5E, a sealing layer 258 has been deposited over at least a portion of the shell layer 254 to seal the aperture 255. The shell layer 254 and sealing layer 258 cooperate to hermetically seal the pixel 200, and may provide some protection against mechanical interference of the sensor 240 from objects or forces external to the sensor. The shell layer 254 and/or one or more layers (not shown) supported thereon may serve as an LWIR window as discussed above to filter incident light 260 to pass only light 262 that is primarily composed of LWIR. Portions of the pixel 200, including for example portions of the underlying TFT 220 and associated structure, may extend outside the boundaries of the hermetic seal, and electrodes 222 and other components may pass under the seal to provide electrical communication with external circuitry.

The deposition of the sealing layer 258 can be done under vacuum or in a low vacuum environment to seal the sensor, so as to achieve a residual pressure after sealing of less than about 0.1 mBar, although in other implementations the residual pressure may be as low as or lower than 0.001 mBar. Alternatively, the sealing may be done at somewhat higher pressures using an ambient gas that has a small molecular cross section such as hydrogen or helium, which in some particular implementations can then be removed from the cavity 232 in a low temperature anneal during which the gas diffuses through and out of the shell layer. Depending on the material and thickness of the material of the shell layer 254, the sealing layer 258 may in some implementations be deposited over the entire shell layer 254 to provide a hermetic seal when the shell layer 254 alone does not provide a desired level of hermeticity.

In the illustrated implementation, the aperture 255 overlies a portion of the sensor 240, requiring that the sealing layer 258 used to seal the aperture 255 be formed from an LWIR-transmissive material. In some implementations, the materials listed above as suitable materials for forming the shell layer may also be utilized as suitable materials for forming an LWIR-transmissive sealing layer 258, although other materials may also be used. In some implementations, the sealing layer 258 may be thinner than the shell layer 254, and may have a thickness between about 10 and 1000 nm, although other thicknesses, including thicknesses similar to that of the shell layer 254 may be used in other implementations. In some implementations, a thin sealing layer can be formed using atomic layer deposition (ALD). In some implementations, the sealing layer 258 can include multiple layers, one or more of which can be formed by atomic layer deposition (ALD). These layers can be formed from the same or from different materials so long as the portion overlying the sensor 240 is sufficiently transmissive to LWIR light.

The pixel 200 may include additional components not depicted in FIG. 5E. For example, the pixel 200 may include an LWIR anti-reflection layer as discussed above, which may be formed at various points in the fabrication process. For example, the LWIR anti-reflection layer may be formed prior to the shell layer 254 such that it is located on the interior of the shell layer 254, or may be formed after one or both of shell layer 254 and the sealing layer 258 so that it is external to the shell layer 254. Similarly, the pixel 200 may be made a reference pixel by depositing an LWIR-opaque material adjacent the shell layer 254 or sealing layer 258, or by using an LWIR-opaque material as the shell layer 254 for that pixel.

FIG. 6 shows an example of a cross-sectional schematic illustration of another implementation of a microbolometer fabricated using a process such as the processes of FIGS. 4A-4D and FIGS. 5A-5E. The pixel 270 shown in FIG. 6 differs from the pixel 200 shown in FIG. 5E in that the aperture formed in the shell layer 254 is laterally offset from the underlying sensor 240. This lateral offset allows the use of a wider range of materials to form the sealing layer 278, as the sealing layer 278 need not be LWIR-transmissive.

The use of a material which is not transmissive to LWIR in the fabrication process may facilitate fabrication of reference pixels, as the pixel 270 can easily be modified to be a reference pixel by extending the LWIR-opaque sealing material 278 to overlie the sensor 240 as well.

FIG. 7 shows an example of a cross-sectional schematic illustration of a device including an array of pixel-level packaged microbolometers and supplemental control and sensing circuitry. In particular, the array of pixel-level packaged microbolometers includes an array of pixels 200, such as the pixel 200 of FIG. 5E, formed over a thin-film active matrix array 294 which may include an array of TFTs 220 (FIG. 5E). The device 202, which may be for example a microbolometer FPA, also includes ancillary control and/or measurement circuitry in the form of a discrete ancillary CMOS substrate 290. In the illustrated implementation, the ancillary CMOS substrate 290 is bonded, either directly or indirectly, to the same glass substrate 210 which supports the array of pixels 200, similar to the implementation depicted in FIG. 3B. However, the ancillary CMOS substrate 290 in the illustrated implementation is formed on the opposite surface of the substrate 210 from the array of pixels 200 and active matrix array 294, and may be in electrical communication with the active matrix array 294 through the use of through-glass vias 292 extending through the substrate 210.

FIG. 8 shows an example of a flow diagram illustrating a manufacturing process for a microbolometer array including a pixel-level packaging process. The method 500 begins at a block 505 at which a plurality of microbolometers are formed over an active matrix array, where each of the microbolometers are surrounded by sacrificial material. As discussed above, the active matrix array can be formed using a thin-film deposition process on a glass substrate, and the microbolometers can be formed over and in electrical communication with the active matrix array. The sacrificial material can be formed in at least two layers at different stages in the fabrication process, but can be removed by a single etch. The sacrificial material can overlie and surround at least a portion of the microbolometers, as discussed above.

The method 500 then moves to a block 510 in which a shell layer is formed over the sacrificial material. As discussed above, at least a portion of the shell layer overlying the microbolometer can include an LWIR-transmissive material.

The method 500 then moves to a block 515 in which an aperture is formed in the shell layer, exposing at least a portion of the sacrificial material. A release etch is then performed to remove the sacrificial layer and release the microbolometer. In some implementations, the aperture is formed over at least a portion of the microbolometer sensor, while in other implementations, the aperture is laterally offset from the microbolometer sensor.

The method 500 then moves to a block 520 where a sealing layer is formed over at least the aperture in the shell layer. In implementations in which the aperture overlies a portion of the underlying sensor, the sealing layer must be substantially LWIR-transmissive to avoid blocking LWIR from reaching the sensor, unless the sensor is intended to form part of a reference pixel. In implementations in which the aperture is laterally offset from the underlying sensor so that a sealing layer can seal the aperture without overlying a portion of the sensor, LWIR-opaque materials can also be used as part of the sealing layer.

In further implementations, additional steps not specifically depicted in FIG. 8 can be performed during, before, or after the blocks depicted in FIG. 8. For example, in some implementations, ancillary control or measurement circuitry in the form of a discrete CMOS substrate can be placed in electrical communication with the active matrix array, as discussed above. In some particular implementations, the CMOS circuitry can be bonded directly or indirectly to the glass substrate, although in other implementations the CMOS circuitry may be positioned away from the glass substrate. Additional components may be formed within the device, including an LWIR anti-reflection layer disposed in the path of light incident upon the sensor, conductive structures such as through-glass vias, flex tapes, traces or leads to place the microbolometer and active matrix arrays in electrical communication with ancillary measurement and/or control circuitry or other inputs and/or outputs, and a wide variety of other additional components, including but not limited to other additional components described herein.

In other implementations, wafer-level packaging may be utilized instead of the pixel-level packaging discussed above. While wafer-level packaging may use a greater amount of LWIR-transmissive material than the pixel-level packaging process discussed above, a wafer-level packaging process such as that described below may nevertheless be simpler and more cost-effective than other microbolometer packaging processes. In one implementation, a glass substrate comprising one or more pixel arrays is provided, and sealed to a facing window substrate to form individual packages sealing each of the pixel arrays. The glass substrate and facing window substrate may then be parted to separate the individual packages, such as through a scribe and break process. The parting may be a multi-step process which enables testing of the individual packages on the wafer.

FIGS. 9A-9G show examples of cross-sectional schematic illustrations of various stages in a method of fabricating a microbolometer array using a wafer-level packaging process. The method illustrated in FIGS. 9A-9G may be performed subsequent to the steps of FIGS. 4A-4D or a similar process of forming an unreleased microbolometer or microbolometer array. As shown in FIG. 9A, the pixels 300 each include a microbolometer sensor 340 spaced apart from an underlying LWIR mirror 330. In some implementations, the pixels 300 are unreleased, and include at least a portion of an underlying sacrificial material, although in some implementations the sacrificial material may be patterned to remove portions of the sacrificial layer extending between pixels 300. The sensors 340 are electrically connected to electrodes 322 and other components such as TFTs within a thin-film active matrix array 320 extending over a portion of the underlying glass substrate 310, also referred to as an array substrate 310. As discussed above, the LWIR mirrors 330 and the electrodes 322 in some embodiments may not be discrete components, but may be part of the underlying active matrix array 320.

In addition, in the illustrated implementation, a passivation layer 328 of a dielectric material has been formed over the array of pixels 300. As discussed in greater detail below, the deposition of this passivation layer 328 facilitates the deposition of subsequent layers such as through an electroplating process, and allows the use of conductive seal layers without shorting of electrical components extending under the conductive seal. In other implementations, however, the passivation layer 328 may not be formed. Although depicted for convenience as extending over the upper and outer surfaces of the components of pixel 300, the passivation layer may be patterned to localize it exclusively to surfaces that are required for sealing. However, it is also possible that the layer could be further extended, for example, by depositing the passivation layer using ALD to cover inner surfaces of the pixel 300 not covered by sacrificial material. Routing electrodes 329, which are discussed above with respect to electrodes 322, may in some implementations be a part of active matrix array 320 and extend beyond the edge of the passivation layer to allow electrical connections with external electrical elements, as discussed in greater detail below.

In FIG. 9B, a seed layer 370b of electroplating material circumscribing the periphery of the array of pixels 300 is deposited over the passivation layer. In some implementations, the seed layer may be a layer of titanium (Ti) or tungsten (W) or an alloy thereof, but other suitable materials may be used instead. In other implementations in which electroplating is not used or metal layers will not be used to form the seal, any suitable material which can form a part of a hermetic seal may be deposited in place of the seed layer 370b such as to provide an adhesion layer to facilitate adhesion to a substrate or passivation layer 328, or no additional material may be deposited at this time.

It can also be seen in FIG. 9B that an LWIR window substrate 350 is also provided. Possible materials for the window substrate 350 include, but are not limited to germanium, low-oxygen silicon, chalcogenides (such as GASIR™ or AMTIR™), zinc sulfide, zinc selenide, gallium arsenide, calcium fluoride, magnesium fluoride, barium fluoride, aluminum oxide (Al₂O₃), sapphire, polyethylene, or PolyIR™. The window substrate may alternately be formed from any other suitable LWIR material such as other suitable LWIR-transmissive material discussed herein. The window substrate 350 may include multiple materials, including LWIR-opaque material in the portions of the window substrate which do not overlie an active pixel.

In the illustrated implementation, the window substrate 350 includes thicker sections 351 surrounding recesses 352 which provide spacing for the underlying array of pixels 300. Other portions of the window substrate 350 not overlying an array of pixels 300 may also be made thinner than the thicker sections 351, so as to facilitate a subsequent parting process, examples of which include sawing, dicing, scribing and breaking, laser ablating, and etching processes. A complementary seed layer 370a substantially identical in shape to that of the seed layer 370b is also formed on a facing surface of the window substrate 350, such as on the thicker portions 351.

In some implementations, the recesses 352 may be formed in a thick window substrate 350 which in some particular implementations was originally a substantially planar substrate with a thickness at least that of the thicker sections 351. In some implementations, the recesses 352 may be between 5 and 50 um deep. In other implementations, the thicker sections 351 may include additional material that was built up on the surface of the substrate 350 to form thicker standoff sections. In still other implementations, if the seal material is sufficiently thick to provide a desired amount of spacing between the interior surface of the window substrate 350, a planar window substrate may be used. In addition, by forming standoffs or using a planar window substrate 350 rather than etching recesses 352 into the window substrate 350, the use of an anti-reflective coating (not shown) on both surfaces of the window substrate 350 overlying the pixels 300 may be facilitated, although anti-reflective coatings may also be formed on patterned substrates.

In FIG. 9C, one or more additional metal layers 372a and 372b are formed on seed layers 370a and 370b, which will form part of a seal between the window substrate 350 and the array substrate 310 to package the array of pixels 300. In some implementations, as discussed above, the metal layers 372a and 372b may be deposited via a non-electroplating process, such as a sputter process or other appropriate deposition process. The metal layers 372a and 372b that form part of the seal may be selected on the basis of metallurgies compatible with low-temperate substrate bonding using thermocompression bonding (in which bonds between atoms on two metal surfaces are formed while they are pressed together and heated) or eutectic bonding (in which a eutectic alloy is formed while two metal surface are pressed together and heated).

In some implementations, the metallurgies are selected to allow bonding at temperatures less than 350° C. to prevent damage to the sensor or active matrix array, but in some implementations higher bonding temperatures may also be used. The allowable bonding temperature range and duration for MEMS sensors such as microbolometers and an associated active matrix array will be performance specific and highly dependent on a variety of factors, including the particular materials used. In some implementations, the allowable temperature range and duration for annealing the TFT circuitry may be a temperature of roughly 300° C. for less than about 30 minutes, although higher temperatures may be permissible for shorter durations, and longer durations may be permissible at lower temperatures. Generally, however, it may be preferable to minimize the temperature and duration of bonding processes.

Possible eutectic metallurgies include gold/tin (Au/Sn), which has a bonding temperature of roughly 280° C.; copper/tin (Cu/Sn), which has a bonding temperature of roughly 231° C.; and gold/indium (Au/In), which has a bonding temperature of roughly 156° C. Possible eutectic metallurgies at higher bonding temperatures include gold/silicon (Au/Si), which has a bonding temperature of roughly 363° C.; and gold/germanium (Au/Ge), which has a bonding temperature of roughly 361° C. In some implementations in which the components are less sensitive to higher temperatures, aluminum/germanium (Al/Ge) eutectic bonding may be used, which has a bonding temperature of roughly 419° C. As noted above, a seed layer or adhesion layer may also be used, which may include titanium, tungsten, or titanium-tungsten alloy. Layers may also be chosen to inhibit oxidation. For example, when tin is used, a gold coating having a thickness of roughly 800 Angstroms or thicker may be used to inhibit oxidation of the tin.

In some implementations, the metal layers 372a and 372b may include multiple metal layers arranged in the following order: a copper (Cu) layer adjacent the seed layer 370a or 370b, a tin (Sn) layer, and a gold (Au) layer. In other implementations, an adhesion layer such as a layer including titanium (Ti), chromium (Cr), or a titanium-tungsten (TiW) alloy may be included adjacent the Cu layer, or may otherwise form a part of metal layers 372a and 372b closest to their respective supporting substrate to improve adhesion between the metal layers 372a and 372b and an adjacent supporting layer. In some implementations, a layer of nickel (Ni) can be used in place of the copper layer, and/or a layer of palladium (Pd) can be used in place of the gold layer. In some implementations, layer of tin can be omitted. In other implementations, fewer layers and/or layers of different metals or metal compositions not explicitly mentioned may also be used.

In FIG. 9D, a release etch has been performed to remove the sacrificial material, and the substrate may also be cleaned at this stage. The array substrate 310 has been sealed to the window substrate 350 by joining metal layers 372a and 372b to one another to form a seal 374 including both the metal layers 372a and 372b and the seed layers 370a and 370b. This sealing may be accomplished through the use of, for example, a thermocompression or eutectic bonding process, in which the substrates 310 and 350 are aligned, and the metal layers 372a and 372b are brought into contact with each other. Pressure is applied at a raised temperature sufficient to create the bond, and the package is annealed under vacuum, forming seal 374 which hermetically seals the array of pixels 300 under vacuum within a package defined at least in part in the illustrated implementation by the recess 352 in the window substrate 350.

As discussed above, a variety of other methods may be used to form seal 374. Plasma treatment can be used to activate bonding surfaces and lower their bonding temperatures to temperatures as low as 150° C., and can be used in conjunction with the thermocompression bonding as discussed above or in another process to greatly increase the possible bonding materials within the allowable temperature range. In some implementations, metal diffusion can be used, by plating layers of like metals on facing substrates and fusing those layers together. Gold will fuse to gold at temperatures between 300 and 400° C., copper will fuse to copper at temperatures between 380 and 450° C., and aluminum will fuse to aluminum at temperatures between 375 and 425° C. Other alternatives include laser annealed compression bonding, anodic bonding, fusion or direct bonding, or the use of lead-based or lead-free frit glass. For example, some commercially available glass bonding materials have low melting temperatures (such as VANEETECT™, sold by Hitachi, Ltd., which can have a melting temperature of about 300° C. or less) and can be melted for adhesion to glass substrates at temperatures exceeding their melting temperature or by localized laser heating. In other implementations, certain solder materials will bond at temps between 150 and 250° C.

FIG. 9D also includes an indication of regions of substrate 350 that may be removed in subsequent steps as part of the testing and/or parting process. In some implementations, a section 356 located in a thin portion of the window substrate 350 adjacent the hermetically sealed package can be parted to allow access to the underlying routing electrodes 329 or to a contact pad or similar structure, as discussed below. Subsequently, the array substrate 310 may be parted at a location 358, as also discussed in greater detail below.

In FIG. 9E, an aperture 357 has been formed in location 356 (see FIG. 9D) in a portion of the window substrate 350 overlying exposed electronic circuitry, such as the routing electrodes 329 or a contact pad, which allows testing of the pixels 300, as well as a test of other properties such as the hermeticity of the seal 374. This aperture may be formed by a shallow dicing process, by deep reactive ion etching (RIE), or by any other suitable process. In some implementations, multiple apertures 357 may be formed in the substrate, such as on more than one side of the array of pixels 300.

In FIG. 9F, a parting process has been performed to singulate the array substrate. For example, substrate 310 can be parted at location 358 (see FIG. 9E) and the window substrate 350 may also be parted as shown. The remaining portion of the array substrate 310 in the illustrated implementation is larger than the remaining portion of the window substrate 350, due to a lip 312 which extends outward from the sealed area and supports the exposed routing electrodes 329 or other electrical connection structure such as a contact pad.

In FIG. 9G, the array substrate 310 has been bonded to an underlying carrier substrate 380 such as a lead frame, using die attach material 382 or another suitable material, forming a device 302 such as an FPA as discussed above. Also bonded to the carrier substrate 380 and laterally displaced from the lip 312 is a CMOS substrate 390 that includes in its function ancillary measurement and/or control circuitry. As discussed above with respect to FIG. 3A, multiple discrete CMOS substrates 390 can be included, although only one is shown in the cross-sectional view of FIG. 9G. An electrical connection is made between the CMOS substrate 390 and the routing electrodes 329 or similar structure connected to active matrix array 320 (see FIG. 9F) using flexible printed circuit 392, although in other implementations wirebonds or electrical traces may also be used. An input and/or output connection (not shown) may also be provided between the CMOS circuitry 390 and external circuitry or devices. In the finished device 302, the portion of window substrate 350 overlying pixels 300 is transmissive to LWIR, such that the portion 362 of incident light 360 which passes through window substrate 350 and reaches the sensors 340 of pixels 300 includes LWIR and may in some implementations be primarily composed of LWIR.

FIG. 10 shows an example of a cross-sectional schematic illustration of a device including an array of pixel-level packaged microbolometers and supplemental control and sensing circuitry. The device 304 of FIG. 10 is similar to the device 302 of FIG. 9G, except that the device 304 includes an encapsulating package 394 which surrounds the CMOS substrate 390 and a portion of the array substrate 310 and window substrate 350 without occluding a portion of the window substrate 350 located over the pixels 300. As discussed above, at least the portion of window substrate 350 overlying pixels 300 is transmissive to LWIR, and the portion 362 of incident light 360 which passes through window 350 includes LWIR and may in some implementations be primarily composed of LWIR. Device 304 also includes one or more external leads 396 extending between the CMOS substrate 390 and the exterior of the encapsulating package 394 to provide for input and/or output to the device 304.

FIG. 11 shows an example of a flow diagram illustrating a manufacturing process for a microbolometer array using a wafer-level packaging process. The process 600 begins at a block 605 where an array of microbolometers are formed on an array substrate. As discussed above, the array substrate may be a glass substrate, and the microbolometers may be formed over a thin-film active matrix array. In some implementations the microbolometers may be at least partially released.

The process 600 then moves to a block 610 where at least one layer of seal material is formed on at least one of the array substrate or a facing surface of the window substrate. In some implementations, in particular those that utilize a conductive seal layer, a passivation layer may be deposited over the array of microbolometers prior to deposition of a seal layer on the array substrate. In some implementations, seal layers may be formed on both the array substrate and the window substrate. As discussed previously, in particular implementations, the seal layers may include materials selected to provide specific metallurgies that allow bonding of the seal layers to one another at temperatures below a threshold temperature.

The process 600 then moves to a block 615 where the array substrate is sealed to the window substrate to form a package encapsulating the microbolometer array. In some implementations, the sealing process may include thermocompression bonding, although the other bonding techniques discussed herein may also be used.

The process 600 moves to a block 620 where both the array substrate and at least one CMOS substrate including ancillary control and/or measurement circuitry are bonded to a carrier substrate such as a lead frame. The CMOS substrate is then placed in electrical communication with the microbolometer array, and may be placed in connection with external circuitry to serve as an input or output component.

In further implementations, additional steps not specifically depicted in FIG. 11 can be performed during, before, or after the blocks depicted in FIG. 11. For example, in some implementations, the CMOS circuitry can be bonded directly or indirectly to the glass substrate. As discussed above with respect to FIG. 8, additional components may be formed within the device, such as an LWIR anti-reflection layer disposed in the path of light incident upon the sensor, conductive structures such as through-glass vias, flexible printed circuits, traces or leads, and a wide variety of other additional components, including but not limited to other additional components described herein.

Even if not specifically noted, the materials and thicknesses described herein are exemplary, and are not intended to be limiting lists or ranges unless specifically noted otherwise. Other suitable materials and/or thicknesses of materials may also be used for each of the structures described herein.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that May be accessed by a computer. Also, any connection can be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., a microbolometer or sensor element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be exoised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus, comprising:
a glass substrate;
an active matrix array formed over the glass substrate, the active matrix array including a plurality of thin-film transistors (TFTs);
an array of microbolometer sensors supported by the glass substrate and electrically connected to the active matrix array, each of the microbolometer sensors including:
a long-wave infrared (LWIR) absorber suspended over the glass substrate; and
a thermistor disposed adjacent the LWIR absorber;
a plurality of shell structures, each shell structure encapsulating a portion of the array of microbolometer sensors, wherein at least a portion of the plurality of shell structures include an LWIR-transmissive layer overlying at least one microbolometer sensor.

2. The apparatus of claim 1, additionally including at least one ancillary CMOS substrate electrically connected to the active matrix array, wherein the at least one ancillary CMOS substrate includes measurement or control circuitry.

3. The apparatus of claim 2, wherein the at least one ancillary CMOS substrate is bonded to the glass substrate.

4. The apparatus of claim 3, wherein the active matrix array and array of microbolometer sensors are located over a first surface of the glass substrate, and wherein the at least one ancillary CMOS substrate is bonded to a second surface of the glass substrate opposite the first surface of the glass substrate.

5. The apparatus of claim 4, additionally including at least one via extending between the first surface of the glass substrate and the second surface of the glass substrate and forming at least a part of an electrical connection between the ancillary CMOS circuitry and the active matrix array.

6. The apparatus of claim 2, wherein each of the glass substrate and the at least one ancillary CMOS substrate are bonded to a carrier substrate.

7. The apparatus of claim 6, wherein at least a portion of the glass substrate, the carrier substrate, and the at least one ancillary CMOS substrate are encapsulated by a packaging material without occluding the array of microbolometer sensors.

8. The apparatus of claim 2, wherein the active matrix array includes a row address decoder and a column output multiplexer.

9. The apparatus of claim 8, additionally including a second ancillary CMOS substrate, wherein:
the first ancillary CMOS substrate is electrically connected to the row address decoder and includes control circuitry; and
the second ancillary CMOS substrate is electrically connected to the column output multiplexer and includes measurement circuitry.

10. The apparatus of claim 1, wherein each of the plurality of shell structures encapsulates a single microbolometer sensor.

11. The apparatus of claim 1, wherein each of the plurality of shell structures include:
a shell layer having an aperture extending therethrough; and
a sealing layer overlying at least the aperture and sealing the aperture.

12. The apparatus of claim 11, wherein the aperture overlies at least a portion of a microbolometer sensor, and wherein the sealing layer includes an LWIR-transmissive material.

13. The apparatus of claim 11, wherein the aperture is laterally offset from any microbolometer sensor within the shell structure, and wherein the sealing layer includes an LWIR-opaque material.

14. The apparatus of claim 1, each microbolometer sensor additionally comprising an LWIR reflector underlying and spaced apart from the LWIR absorber and the thermistor.

15. The apparatus of claim 14, wherein the LWIR reflector includes a getter material.

16. The apparatus of claim 1, wherein at least a portion of the microbolometer sensors serve as reference pixels.

17. The apparatus of claim 16, wherein the apparatus additionally includes an LWIR-opaque material overlying the microbolometer sensors that serve as reference pixels.

18. The apparatus of claim 16, wherein the microbolometer sensors that serve as reference pixels are thermally sunk to the array substrate.

19. The apparatus of claim 1, wherein each shell structure forms a hermetically sealed cavity supported by the glass substrate and encapsulating a portion of the array of microbolometer sensors.

20. The apparatus of claim 19, wherein the pressure within the hermetically sealed cavity is less than about 0.1 mbar.

21. The apparatus of claim 1, wherein the apparatus is an LWIR camera, and wherein the array substrate, the active matrix array, the array of microbolometer sensors, and plurality of shell structures form a part of a focal plane array within the LWIR camera.

22. A method of fabricating a microbolometer device; comprising:
forming an active matrix array over a glass substrate, wherein the active matrix array includes a plurality of thin-film transistors (TFTs);
forming an array of microbolometer sensors over at least a portion of the active matrix array, wherein each of the microbolometer sensors include:
a long-wave infrared (LWIR) absorber suspended over the glass substrate; and
a thermistor disposed adjacent the LWIR absorber;
forming at least one hermetically-sealed package encapsulating the array of microbolometer sensors and including an LWIR-transmissive layer overlying at least one of the microbolometer sensors; and
electrically connecting the active matrix array to at least one ancillary CMOS substrate including measurement or control circuitry.

23. The method of claim 22, wherein forming an active matrix array additionally includes forming a row address decoder and a column output multiplexer, and wherein electrically connecting the active matrix array to at least one ancillary CMOS substrate including measurement or control circuitry includes:
electrically connecting a first ancillary CMOS substrate including control circuitry to the row address decoder; and
electrically connecting a second ancillary CMOS substrate including measurement circuitry to the column output multiplexer.

24. The method of claim 22, wherein forming a plurality of shell structures includes:
forming discrete sections of sacrificial material over each of the microbolometer sensors;
forming a shell structure over each of the discrete sections of sacrificial material, each shell structure including an aperture extending therethrough;
performing a release etch to remove the discrete sections of sacrificial material; and
forming a sealing layer over at least the aperture to close the aperture.

25. The method of claim 24, wherein the sealing layer extends over at least a portion of a microbolometer sensor and includes an LWIR-transmissive material.

26. The method of claim 24, wherein the sealing layer is laterally offset from any microbolometer sensor within the shell structure and includes an LWIR-opaque material.

27. An apparatus, comprising:
a glass substrate;
an active matrix array formed over the glass substrate, the active matrix array including a plurality of thin-film transistors (TFTs);
an array of microbolometer sensors supported by the glass substrate and electrically connected to the active matrix array, each of the microbolometer sensors including:
a long-wave infrared (LWIR) absorber suspended over the glass substrate; and
a thermistor disposed adjacent the LWIR absorber;
means for hermetically encapsulating discrete portions of the array of microbolometer sensors; and
an LWIR-transmissive layer overlying at least one of the microbolometer sensors.

28. The apparatus of claim 27, additionally including at least one ancillary CMOS substrate electrically connected to the active matrix array.

29. The apparatus of claim 27, wherein the encapsulating means include a plurality of shell structures, each shell structure separately encapsulating only a portion of the array of microbolometer sensors.

30. The apparatus of claim 29, wherein each of the plurality of shell structures encapsulates only a single microbolometer sensor.

31. The apparatus of claim 29, wherein a portion of a shell structure serves as the LWIR-transmissive layer.

32. The apparatus of claim 27, wherein a shell structure supports the LWIR-transmissive layer.
